(19) United States
(12) Patent Application Publication
(10) Pub. No.: US 2026/0107383 A1
(43) Pub. Date: Apr. 16, 2026

(54) WIRING BOARD AND MOUNTING STRUCTURE USING THE WIRING BOARD

(71) Applicant: Kyocera Corporation, Kyoto-shi, Kyoto (JP)

(72) Inventor: Hidetoshi YUGAWA, Kyoto-shi, Kyoto (JP)

(73) Assignee: Kyocera Corporation, Kyoto-shi, Kyoto (JP)

(21) Appl. No.: 19/116,741

(22) PCT Filed: Sep. 25, 2023
(86) PCT No.: PCT/JP2023/034644

§ 371 Date: Mar. 28, 2025

(30) Foreign Application Priority Data
Sep. 30, 2022 (JP) 2022-157395
May 30, 2023 (JP) 2023-088732

(51) Int. Cl. H05K 1/11; H10W 70/63

(52) U.S. Cl. CPC H05K 1/113; H10W 70/63; H05K 2201/0344; H05K 2201/09563

(57) ABSTRACT

A wiring board according to the present disclosure includes: a first insulation layer having a first surface; a land conductor located on the first surface; a second insulation layer covering the first surface and the land conductor and having a second surface on a side opposite to the first insulation layer; a via hole penetrating from the second surface of the second insulation layer to the land conductor; and a via hole conductor located in the via hole and in contact with the land conductor. The via hole conductor includes an underlying metal layer and an electrolytic plating layer located on the underlying metal layer, the underlying metal layer being located on a surface of the land conductor, a wall surface of the via hole, and the second surface. A plurality of voids are located in at least a portion of the underlying metal layer.

### TECHNICAL FIELD

The present disclosure relates to a wiring board and a mounting structure using the wiring board.

### BACKGROUND OF INVENTION

In a wiring board, in order to electrically connect electrical conductor layers located on upper and lower surfaces of an insulation layer, a conductor (via hole conductor) is filled in a via (via hole) formed in the insulation layer as illustrated in Patent Document 1. The via hole conductor is usually connected to the via land at the via bottom. In the via hole conductor, stress tends to concentrate on a connection portion between the via bottom and the via land due to a difference in thermal expansion coefficient between the via hole conductor such as copper and the resin forming the insulation layer. Therefore, for example, when exposed to a high temperature condition, it is easily broken.

### CITATION LIST

### Patent Literature

Patent Document 1: JP 2007-27341 A

### SUMMARY

### Solution to Problem

A wiring board according to the present disclosure includes: a first insulation layer having a first surface; a land conductor located on the first surface; a second insulation layer covering the first surface and the land conductor and having a second surface on a side opposite to the first insulation layer; a via hole penetrating from the second surface of the second insulation layer to the land conductor; and a via hole conductor located in the via hole and in contact with the land conductor. The via hole conductor includes an underlying metal layer and an electrolytic plating layer located on the underlying metal layer, the underlying metal layer being located on a surface of the land conductor, a wall surface of the via hole, and the second surface. A plurality of voids are located in at least a portion of the underlying metal layer.

A mounting structure according to the present disclosure includes the wiring board described above, and an electronic component located at a mounting region of the wiring board.

### BRIEF DESCRIPTION OF THE DRAWINGS

FIG. 1 is an explanatory view for explaining a wiring board according to one embodiment of the present disclosure.

FIG. 2 is an enlarged cross-sectional view for explaining a region X illustrated in FIG. 1.

FIG. 3 is an enlarged cross-sectional view for explaining a region Y illustrated in FIG. 2.

FIGS. 4A-E are an explanatory diagram for explaining an example of a method of forming a via hole conductor in the wiring board according to one embodiment of the present disclosure.

FIGS. 5A-D are an explanatory diagram for explaining an example of a method of forming a via hole conductor in a wiring board according to another embodiment of the present disclosure.

FIGS. 6A-D are an explanatory diagram for explaining an example of a method of forming a via hole conductor in a wiring board according to another embodiment of the present disclosure.

FIGS. 7A-C are an explanatory diagram for explaining an example of a method of forming a via hole conductor in a wiring board according to another embodiment of the present disclosure.

### DESCRIPTION OF EMBODIMENTS

As described above, in the via hole conductor, stress tends to concentrate on the connection portion between the via bottom and the via land due to the difference in thermal expansion coefficient between the via hole conductor and the resin forming the insulation layer. Therefore, for example, when exposed to a high temperature condition, it is easily broken. Therefore, a wiring board having excellent connection reliability of a via hole conductor and a mounting structure using the wiring board are required.

The wiring board and the mounting structure according to the present disclosure are excellent in connection reliability of the via hole conductor by having the configuration described in the section of SOLUTION TO PROBLEM.

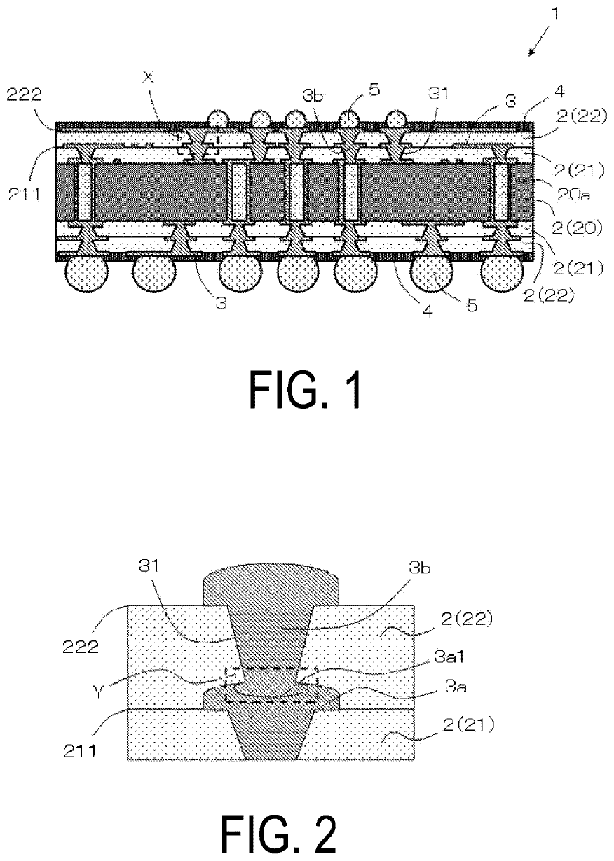

A wiring board according to one embodiment of the present disclosure will be described with reference to FIGS. 1 and 2. FIG. 1 is an explanatory view for explaining a wiring board 1 according to one embodiment of the present disclosure. As illustrated in FIG. 1, a wiring board 1 according to one embodiment includes an insulation layer 2, an electrical conductor layer 3, and a solder resist 4.

The insulation layer 2 includes a core insulation layer 20, a first insulation layer 21, and a second insulation layer 22. The core insulation layer 20 is not particularly limited as long as it is a material having insulation properties. Examples of a material with insulation properties include resins such as epoxy resin, bismaleimide-triazine resin, polyimide resin, and polyphenylene ether resin. Two or more types of the resin may be mixed and used. The thickness of the core insulation layer 20 is not particularly limited, and is, for example, from 20 μm to 10 mm. The core insulation layer 20 is not necessarily required. For example, the core insulation layer 20 is not used in a substrate called a coreless substrate or a 2.3D substrate. For example, as in the case of a motherboard, the thickness of the core insulation layer 20 may exceed 10 mm.

The core insulation layer 20 may contain a reinforcing material. Examples of the reinforcing material include insulation fabric materials such as glass fibers, glass nonwoven fabrics, aramid nonwoven fabrics, aramid fibers, and polyester fibers. Two or more types of reinforcing materials may be used in combination. Inorganic insulation fillers such as silica, barium sulfate, talc, clay, glass, calcium carbonate, and titanium oxide may be dispersed in the core insulation layer 20.

In the core insulation layer 20, a through-hole conductor 20a is located to electrically connect the upper and lower surfaces of the core insulation layer 20. The through-hole conductor 20a is located in the through-hole penetrating from the upper surface to the lower surface of the core insulation layer 20. The through-hole conductor 20a is formed by, for example, metal plating such as copper plating. The through-hole conductor 20a is connected to the electrical conductor layer 3 formed on both surfaces of the core insulation layer 20. The through-hole conductor 20a may be located only on the inner wall surface of a through-hole or may be filled in the through-hole.

The electrical conductor layer 3 is not limited as long as it is a conductor of a metal such as copper, nickel, chromium, or an alloy thereof (for example, nichrome). Specifically, the electrical conductor layer 3 is made of a metal foil such as a copper foil, metal plating such as copper plating, a sputtered metal layer, or the like. The thickness of the electrical conductor layer 3 is not particularly limited, and is, for example, 1 μm or more and 30 μm or less. The thickness of the electrical conductor layer 3 tends to decrease as the wiring becomes finer.

On both surfaces of the core insulation layer 20, a build-up layer in which the electrical conductor layer 3 and the insulation layer 2 are alternately laminated is positioned. The build-up layer has a structure in which the electrical conductor layer 3 and the insulation layer 2 are alternately laminated. In the wiring board 1 according to one embodiment, when attention is focused on any two insulation layers 2 in contact with each other among the insulation layers 2 constituting the build-up layer, the insulation layer 2 on the side closer to the core insulation layer 20 corresponds to the first insulation layer 21, and the other insulation layer 2 corresponds to the second insulation layer 22.

Specifically, when the number of the insulation layers 2 constituting the build-up layer is three, focusing on the insulation layer 2 (the first insulation layer 2) located on the surface of the core insulation layer 20 and the insulation layer 2 (the second insulation layer 2) located on the surface of the first insulation layer 2, the first insulation layer 2 on the side closer to the core insulation layer 20 corresponds to the first insulation layer 21, and the second insulation layer 2 corresponds to the second insulation layer 22. Focusing on the second insulation layer 2 and the insulation layer 2 (third insulation layer 2) located on the surface of the second insulation layer 2, the second insulation layer 2 on the side closer to the core insulation layer 20 corresponds to the first insulation layer 21, and the third insulation layer 2 corresponds to the second insulation layer 22.

Similarly to the core insulation layer 20, the insulation layer 2 (the first insulation layer 21 and the second insulation layer 22) constituting the build-up layer is not particularly limited as long as it is a material having insulation properties. As mentioned above, resins such as epoxy resins, bismaleimide-triazine resins, polyimide resins and polyphenylene ether resins may be mentioned. Two or more types of the resin may be mixed and used. The insulation layers 2 constituting the build-up layer may be made of the same resin or different resins. The insulation layer 2 and the core insulation layer 20 constituting the build-up layer may be made of the same resin or different resins. The thickness of the insulation layer 2 constituting the build-up layer is not particularly limited, and is, for example, from 1 μm to 60 μm. The insulation layers 2 constituting the build-up layer may have the same thickness or different thicknesses.

The insulation layer 2 constituting the build-up layer may contain a reinforcing material. Examples of the reinforcing material include insulation fabric materials such as glass fibers, glass nonwoven fabrics, aramid nonwoven fabrics, aramid fibers, and polyester fibers. Two or more types of reinforcing materials may be used in combination. Inorganic insulation fillers such as silica, alumina, aluminum oxide, barium sulfate, talc, clay, glass, calcium carbonate, or titanium oxide may be dispersed in the insulation layer 2 constituting the build-up layer. In general, in a substrate intended for fine wiring, the inorganic insulation filler such as silica or alumina, which is not chemically corroded by an acid or an alkali, is often used. As a result, insulation deterioration such as ion migration is reduced under high temperature and high humidity or under applied conditions.

As illustrated in FIG. 1, the solder resist 4 may be located on the surface of the build-up layer. The solder resist 4 is made of a resin, such as an acrylic modified epoxy resin. The solder resist 4 is provided with an opening for electrically connecting the electrical conductor layer 3 and an electrode of an element via the solder 5. Examples of the element include a semiconductor integrated circuit element and an optoelectronic element.

A via hole conductor 3b for electrically connecting the upper and lower surfaces of the insulation layer 2 constituting the build-up layer is formed in the insulation layer 2 constituting the build-up layer. The via hole conductor 3b is located in the via hole 31 formed so as to penetrate the insulation layer 2 constituting the build-up layer. That is, as illustrated in FIG. 2, the via hole conductor 3b is located in the via hole 31 penetrating from the second surface 222 of the second insulation layer 22 to the land conductor 3a. FIG. 2 is an enlarged cross-sectional view for explaining a region X illustrated in FIG. 1. The second insulation layer 22 covers the first surface 211 of the first insulation layer 21 and the land conductor 3a located on the first surface 211. The second surface 222 of the second insulation layer 22 is a surface on a side opposite to the first insulation layer 21.

As illustrated in FIG. 2, the via hole conductor 3b is filled in the via hole 31 formed in the second insulation layer 22, and the bottom portion (bottom surface on a side closer to the first surface 211) of the via hole conductor 3b is in contact with the land conductor 3a. The land conductor 3a and the via hole conductor 3b are portions of the electrical conductor layer 3, and are made of metals such as copper.

The via hole conductor 3b includes an underlying metal layer located on the surface of the land conductor 3a, the wall surface of the via hole 31, and the second surface 222, and an electrolytic plating layer 3b2 located on the underlying metal layer. That is, the underlying metal layer is located between the surface of the land conductor 3a, the wall surface of the via hole 31, the second surface 222, and the electrolytic plating layer 3b2. As a result, the electrolytic plating layer 3b2 can firmly adhere to the surface of the land conductor 3a, the wall surface of the via holes 31, and the second surface 222 via the underlying metal layer.

The underlying metal layer is made of a metal such as copper, nickel, chromium, or an alloy thereof (for example, nichrome). The underlying metal layer may be the electroless plating layer 3b1 or the sputtered metal layer 8. When the underlying metal layer is the sputtered metal layer 8, the underlying metal layer may have a multilayer structure in which the sputtered metal layer 8 made of nichrome is located on the sputtered metal layer 8 made of copper, for example.

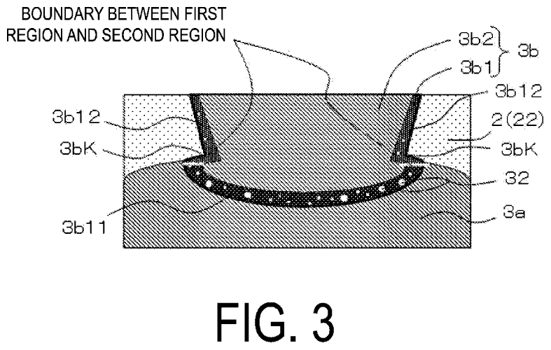

FIG. 3 illustrates an example in which the underlying metal layer is the electroless plating layer 3b1. As illustrated in FIG. 3, the via hole conductor 3b includes the electroless plating layer 3b1 and an electrolytic plating layer 3b2. FIG. 3 is an enlarged cross-sectional view for explaining a region Y illustrated in FIG. 2. The electroless plating layer 3b1 is located on the surface of the land conductor 3a, the wall surface of the via hole 31, and the second surface 222. The thickness of the electroless plating layer 3b1 is not particularly limited, and is, for example, from 100 nm to 3 μm. The electrolytic plating layer 3b2 is located on the electroless plating layer 3b1. The electroless plating layer 3b1 and the electrolytic plating layer 3b2 are made of metals such as copper.

In the wiring board 1 according to one embodiment, as illustrated in FIG. 3, a plurality of voids 32 are located in at least a part of the electroless plating layer 3b1. In the wiring board 1 according to one embodiment, the presence of the void 32 reduces stresses applied to the bottom of the via hole conductor 3b. As a result, the breakage of the via hole conductor 3b is reduced, and the connection reliability of the via hole conductor 3b is improved.

Rather than being regularly arranged, the voids 32 are preferably located so as to be irregularly dispersed. When the voids 32 are positioned so as to be irregularly dispersed, stresses applied in various directions to the bottom portion of the side via hole conductor 3b are more easily relaxed. The size of the void 32 may be, for example, from 1 nm to 300 nm at the largest portion, or may be from 1 nm to 100 nm.

As illustrated in FIG. 2, the land conductor 3a may include, at their peripheral edge, an inclined portion that is inclined with respect to the first surface 211 of the first insulation layer 21. The thickness of the inclined portion may increase from the peripheral edge of the land conductor 3a to the side surface of the via hole conductor 3b in a cross-sectional view. For example, in a cross section including the center of the land conductor 3a in a plan view, the thickness increases from the peripheral edge of the land conductor 3a to the side surface of the via hole conductor 3b. With such a configuration, stresses applied from the insulation layer 2 to the via hole conductor 3b can be further dispersed.

As illustrated in FIG. 2, the land conductor 3a may each include a concave portion 3a1 that is recessed in a curved shape in a cross-sectional view. The via hole conductor 3b may be in contact with the concave portion 3a1. The concave portion 3a1 has, for example, a concave shape recessed from the second surface 222 side toward the first surface 211 side. With such a configuration, stresses applied to the via hole conductor 3b can be further reduced as compared with the case where the via hole conductor 3b and the land conductor 3a are in contact with each other in a plane shape.

The via hole conductor 3b may include a constricted portion 3bK having the smallest horizontal width along the first surface 211. The plurality of voids 32 may be located closer to the land conductor 3a than the constricted portion 3bK at least in the direction perpendicular to the first surface 211 in the via hole conductor 3b. The constricted portion 3bK can be defined as, for example, a portion where the length of the via hole conductor 3b in the lateral direction along the first surface 211 is the smallest. With such a configuration, the point at which the densities of the voids 32 change can be shifted from the boundary between the constricted portion 3bK and the insulation layer 2 (second insulation layer 22) where the stresses are most concentrated. As a result, the breakage of the via hole conductor 3b can be further reduced.

In the electroless plating layer 3b1, the concentration of the plurality of voids 32 included in a first region 3b11 may be higher than the concentration of the plurality of voids 32 included in a second region 3b12. The first region 3b11 is a region located between the electrolytic plating layer 3b2 and the land conductor 3a. The second region 3b12 is a region located between the electrolytic plating layer 3b2 and the second insulation layer 22. The concentration of the plurality of voids 32 included in the first region 3b11 may be more than 100% and about 150% or less of the concentration of the plurality of voids 32 included in the second region 3b12. With such a configuration, stresses applied between the via hole conductor 3b and the land conductor 3a to which larger stresses are applied can be further reduced.

For example, the first region 3b11 in the underlying metal layer may include one or more and forty or less voids 32 per 1000000 nm² in a cross-sectional view. As illustrated in FIG. 3, for example, in a case where the underlying metal layer is the electroless plating layer 3bl, one or more and forty or less voids 32 may be included per 1000000 nm². In a case where the underlying metal layer is the sputtered metal layer 8, one or more and ten or less voids 32 may be included per 1000000 nm².

In a case where the underlying metal layer has a multilayer structure in which the sputtered metal layer 8 made of nichrome is located on the sputtered metal layer 8 made of copper, for example, when the number of the voids 32 of the sputtered metal layer 8 made of copper having a low Young's modulus is larger than the number of the voids 32 of the sputtered metal layer 8 made of nichrome, the buffering action is large, and the stress relaxation effect is more likely to be obtained. In a case where a sputtered layer made of nichrome having a higher Young's modulus than copper is located at the via bottom where stress is likely to concentrate, the stress relaxation effect due to the arrangement of the voids 32 is high. Since the sputtered layer at the via bottom is formed so as to be close to the interface between the electrolytic plating layer 3b2 and the land conductor 3a, the stress relief effect due to the arrangement of the voids 32 is high. The number of the plurality of voids 32 can be confirmed, for example, by photographing and observing with an FE-SEM at a magnification of about 35000 times. In order to reduce cracks when stress is applied to the wiring board 1, the number of the plurality of voids 32 may be one or more and five or less.

The space between the electrolytic plating layer 3b2 and the land conductor 3a is defined as, for example, a space between imaginary lines connecting the electrolytic plating layer 3b2 and the land conductor 3a in parallel to the first surface 211 at the shortest distances. Similarly, the space between the electrolytic plating layer 3b2 and the second insulation layer 22 is defined as, for example, a space between imaginary lines connecting the electrolytic plating layer 3b2 and the second insulation layer 22 in parallel to the first surface 211 at the shortest distances.

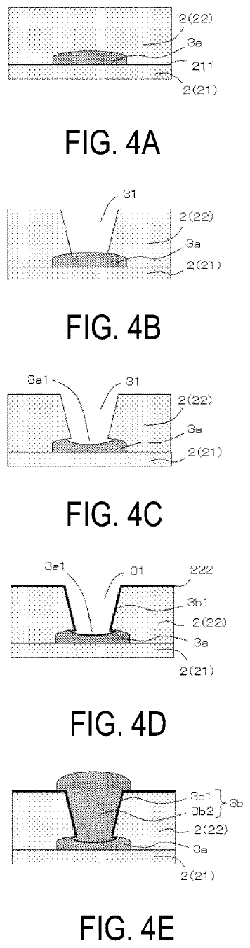

One embodiment of a method of forming the via hole conductor 3b in the via hole 31 will be described with reference to FIG. 4. FIG. 4 is an explanatory diagram for explaining an example of a method of forming the via hole conductor 3b in the wiring board 1 according to one embodiment.

First, as illustrated in FIG. 4A, the land conductor 3a is formed on the first surface 211 of the first insulation layer 21. As described above, the land conductor 3a is a part of the electrical conductor layer 3 and is made of a metal such as copper. Next, as illustrated in FIG. 4B, the via hole 31 is formed in the second insulation layer 22. The via hole 31 is formed so as to penetrate from the second surface 222 of the second insulation layer 22 to the land conductor 3a. The via hole 31 is formed by, for example, laser processing or a photographic method of a photosensitive insulating resin. For the laser processing, a carbon dioxide gas laser, a YAG laser, or an excimer laser is used. The photosensitive insulating resin is generally epoxy, polyimide, or the like, but other resins may be used.

After the via hole 31 is formed, as illustrated in FIG. 4C, the concave portion 3a1 that is recessed in a curved shape is formed on the surface of the land conductor 3a that are the bottom portion of the via hole 31. The concave portion 3a1 is formed by, for example, etching.

Next, as illustrated in FIG. 4D, the electroless plating layer 3b1 is formed on the second surface 222 of the second insulation layer 22, the inner wall of the via hole 31, and the bottom surface of the via hole 31 (the concave portion 3a1 of the land conductor 3a). As described above, the electroless plating layer 3b1 is made of a metal such as copper. As described above, the thickness of the electroless plating layer 3b1 is, for example, from 100 nm to 3 μm.

After the electroless plating layer 3b1 is formed, the electroless plating layer 3b1 is subjected to heat treatment. To be specific, the substrate on which the electroless plating layer 3b1 is formed is heated at a temperature of, for example, 150° C. or higher. The upper limit of the heating temperature is about 180° C. The heating time is, for example, 30 minutes or more, and about 120 minutes at the longest. By subjecting the electroless plating layer 3b1 to the heat treatment, the void 32 is easily formed in the electroless plating layer 3b1.

To be specific, when the heat treatment is performed at a relatively high temperature of 150° C. or more, hydrogen present in the electroless plating layer 3b1 (hydrogen derived from the plating solution) gathers. As a result, fine void 32 having a diameter equal to or smaller than 100 nm is formed. Further, an oxide film is formed on the electroless plating layer 3b1, and at the time of bonding between copper atoms and oxygen atoms at that time, the copper atoms move to generate voids. As a result, the void 32 having a diameter equal to or larger than 50 nm and equal to or smaller than 200 nm is formed.

Next, as illustrated in FIG. 4E, the electrolytic plating layer 3b2 is formed on the surface of the electroless plating layer 3b1, and the via hole 31 is filled with the electrolytic plating layer 3b2. As described above, the electrolytic plating layer 3b2 is made of a metal such as copper. Next, the electroless plating layer 3b1 exposed from the electrolytic plating layer 3b2 is removed by flash etching, and then subjected to a second heat treatment. The second heat treatment is performed at a temperature of, for example, 190° C. or higher. The upper limit of the heating temperature is about 250° C. The heating time is, for example, 20 minutes or more, and about 120 minutes at the longest.

By performing the second heat treatment, it becomes easy to randomize the size and position of the voids 32. To be specific, when the electroless plating layer 3b1 is made of copper, metals other than copper contained as an impurity are diffused to form the voids 32. Therefore, the formed voids 32 are dispersed, and the voids 32 can be arranged at random. In this manner, in the wiring board 1 according to one embodiment, the via hole conductor 3b is formed in the via hole 31 as illustrated in FIG. 2.

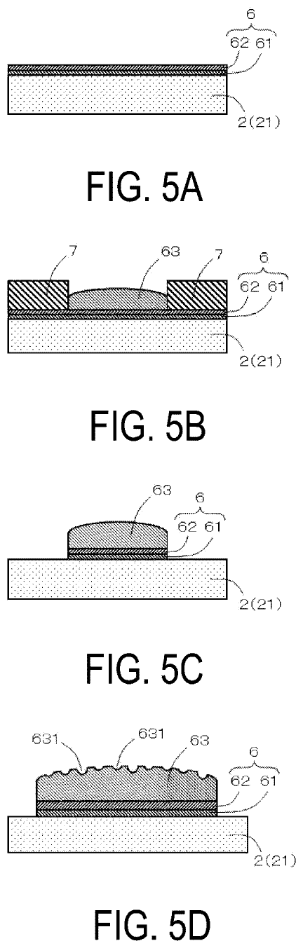

An embodiment in which the underlying metal layer is the sputtered metal layer 8 will be described with reference to FIGS. 5 to 7. FIGS. 5 to 7 are explanatory diagrams for explaining an example of a method of forming the via hole conductor 3b in a wiring board according to another embodiment of the present disclosure. In the wiring board according to the other embodiment, the same members as those of the wiring board 1 according to the one embodiment are denoted by the same reference numerals, and detailed description thereof is omitted.

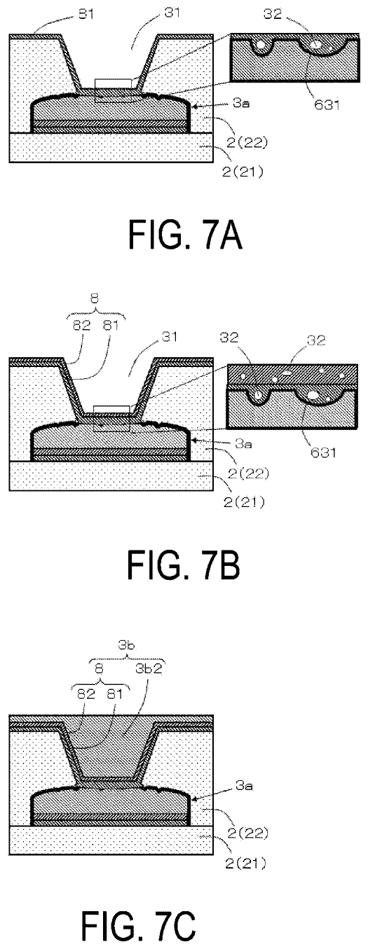

In the wiring board 1 according to one embodiment described above, the underlying metal layer is the electroless plating layer 3b1. On the other hand, in a wiring board according to another embodiment, as illustrated in FIG. 7C, the underlying metal layer is a sputtered metal layer 8. In the wiring board according to the other embodiment, the via hole conductor 3b is formed, for example, as follows.

As illustrated in FIG. 5A, a seed layer 6 is formed on the first insulation layer 21. In FIG. 5A, the seed layer 6 has a two-layer structure of a first seed layer 61 and a second seed layer 62. First, the first seed layer 61 is formed on the surface of the first insulation layer 21. A method of forming the first seed layer 61 is not limited, and the first seed layer 61 is formed by, for example, sputtering. The first seed layer 61 is made of, for example, at least one metal selected from the group consisting of Group 4 elements, Group 5 elements, Group 6 elements, and Group 10 elements. Specific examples of such a metal include nickel, chromium, titanium, tantalum, molybdenum, tungsten, palladium, and alloys containing these metals. The first seed layer 61 may be, for example, a nichrome layer formed by sputtering. The first seed layer 61 may have a thickness of, for example, from 0.5 nm to 100 nm.

Next, the second seed layer 62 is formed on the surface of the first seed layer 61. The method of forming the second seed layer 62 is not limited, and the second seed layer 62 is formed by, for example, sputtering. The second seed layer 62 is made of copper. The second seed layer 62 may have a thickness of, for example, from 100 nm to 1000 nm.

Next, as illustrated in FIG. 5B, a resist 7 is formed on the seed layer 6. The resist 7 has an opening, and an electrolytic plating layer 63 is formed in the opening as illustrated in FIG. 5B. The electrolytic plating layer 63 is, for example, an electrolytic copper plating layer. After the electrolytic plating layer 63 is formed, as illustrated in FIG. 5C, the resist 7 and the seed layer 6 covered with the resist 7 are removed. The resist 7 is stripped with a sodium hydroxide aqueous solution or an amine-based resist stripper.

When the second seed layer 62 of the seed layer 6 is made of copper, the second seed layer 62 is etched using a sulfuric acid-hydrogen peroxide mixture, and then the first seed layer 61 is etched using an etchant suitable for etching the metal of the first seed layer 61. For example, nichrome is removed by etching with a mixed aqueous solution of sulfuric acid and hydrochloric acid.

Next, as illustrated in FIG. 5D, depressions 631 is formed in the surface of the electrolytic plating layer 63. The depressions 631 are formed by performing an annealing treatment under the conditions of, for example, 150° C. or more and 250° C. or less and 20 minutes or more and 90 minutes or less. At this time, the depression 631 has, for example, a diameter from 50 nm to 1000 nm, and a depth from 50 nm to 300 nm.

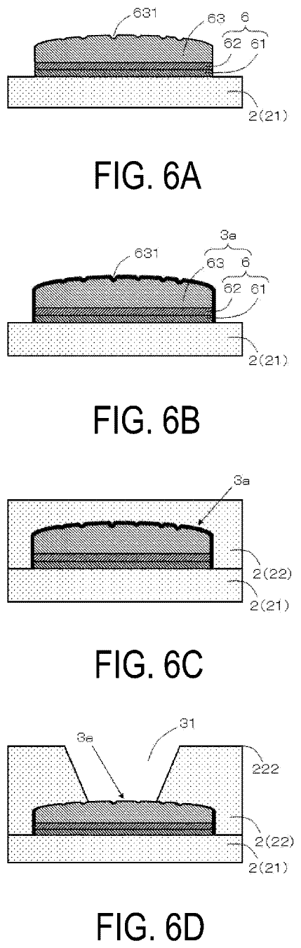

Next, as illustrated in FIG. 6A, soft etching is performed on the surface of the electrolytic plating layer 63, and for example, the diameter of the depression 631 is set to be from 10 nm to 500 nm, and the depth thereof is set to be from 5 nm to 50 nm. After the soft etching treatment, as illustrated in FIG. 6B, a silane coupling treatment is performed on the surfaces of the electrolytic plating layers 63. Specifically, the surface of the electrolytic plating layer 63 is subjected to tin plating, then treated with nitric acid, and subjected to silane coupling treatment. In this manner, the land conductor 3a is formed on the surface of the first insulation layer 21.

Next, as illustrated in FIG. 6C, the second insulation layer 22 is formed on the surface of the first insulation layer 21 so as to cover the land conductor 3a. After the second insulation layer 22 is formed, as illustrated in FIG. 6D, the via hole 31 is formed so as to penetrate from the second surface 222 of the second insulation layer 22 to the land conductor 3a. After the via hole 31 is formed, the concave portion 3a1 that is recessed in a curved shape is formed on the surface of the land conductor 3a that is the bottom portion of the via hole 31. The concave portion 3a1 is formed by, for example, etching. At this time, the silane coupling layer and the tin plating layer formed on the surface of the land conductor 3a are removed. The etching amount is adjusted so that the concave amount of the concave portion 3a1 is smaller than that in a case of electroless plating.

Next, as illustrated in FIG. 7A, a first sputtered metal layer 81 is formed on the second surface 222 of the second insulation layer 22, the inner wall of the via hole 31, and the bottom surface of the via hole 31 (the surface of the land conductor 3a). The first sputtered metal layer 81 is made of, for example, at least one metal selected from the group consisting of Group 4 elements, Group 5 elements, Group 6 elements, and Group 10 elements. Specific examples of such a metal include nickel, chromium, titanium, tantalum, molybdenum, tungsten, palladium, and alloys containing these metals. The first sputtered metal layer 81 may be, for example, a nichrome layer formed by sputtering. The first sputtered metal layer 81 may have a thickness of, for example, from 0.5 nm to 100 nm.

When sputtering is performed on the surface of the land conductor 3a having the depression 631, the entrance of the depression 631 is blocked before the depression 631 is filled with a metal. As a result, as illustrated in FIG. 7A, the void 32 is easily formed in the depression 631.

Next, as illustrated in FIG. 7B, a second sputtered metal layer 82 is formed on the first sputtered metal layer 81. The second sputtered metal layer 82 is made of, for example, copper. The second sputtered metal layer 82 may be, for example, a copper layer formed by sputtering. The second sputtered metal layer 82 may have a thickness of, for example, from 50 nm to 1000 nm. The sputtered metal layer 8 may have a thickness of, for example, from 50 nm to 1100 nm.

When the second sputtered metal layer 82 is formed, for example, by adjusting the setting of the sputtering device, such as reducing the amount of oscillation of the magnet of the sputtering device, unevenness is easily generated in the second sputtered metal layer 82. As a result, as illustrated in FIG. 7B, the void 32 is also easily formed in the second sputtered metal layer 82.

Next, as illustrated in FIG. 7C, the electrolytic plating layer 3b2 is formed on the surface of the second sputtered metal layer 82 (sputtered metal layer 8), and the via hole 31 is filled with the electrolytic plating layer 3b2. As described above, the electrolytic plating layer 3b2 is made of a metal such as copper. By such a procedure, the via hole conductor 3b is formed in the wiring board according to the other embodiment.

A mounting structure according to the present disclosure will be described. A mounting structure according to one embodiment includes the wiring board 1 according to one embodiment and an element located on a surface of the wiring board 1. The electrical conductor layer 3 in the opening of the solder resist 4 and the electrode of the element are connected via solder 5. Examples of the element include a semiconductor integrated circuit element and an optoelectronic element, as described above. The element may be located on both surfaces of the wiring board 1, or the element may be located on one surface of the wiring board 1 and a motherboard, for example, may be located on the other surface thereof.

The wiring board according to the present disclosure is not limited to the wiring board 1 according to one embodiment described above and the wiring board according to another embodiment. In the wiring board 1 according to one embodiment, the insulation layer 2 constituting the build-up layer has a two-layer structure. However, the insulation layer constituting the build-up layer in the wiring board according to the present disclosure is not limited to the two-layer structure, and may have a laminated structure of three or more layers.

In the wiring board 1 according to one embodiment and the wiring board according to another embodiment, the surface of the land conductor 3a is inclined toward the peripheral edge in a cross-sectional view. However, in the wiring board according to the present disclosure, the surface of the land conductor may be substantially parallel to the first surface of the first insulation layer.

In the wiring board 1 according to one embodiment, the land conductor 3a each has the concave portion 3a1 that is recessed in a curved shape in a cross-sectional view. However, in the wiring board according to the present disclosure, the land conductor may not have a concave portion, and even when the land conductor has a concave portion, the land conductor may not have a shape recessed in a curved shape.

In the wiring board according to another embodiment, the sputtered metal layer 8 is made of two layers of the first sputtered metal layer 81 and the second sputtered metal layer 82. However, in the wiring board according to the present disclosure, the sputtered metal layer 8 may have a single-layer structure or a multilayer structure.

The invention according to the present disclosure is not limited to the above-described embodiment, and various changes or improvements can be made within the scope of the present disclosure described in (1) and (12) below.
(1) A wiring board according to the present disclosure includes: a first insulation layer having a first surface; a land conductor located on the first surface; a second insulation layer configured to cover the first surface and the land conductor and including a second surface on a side opposite to the first insulation layer; a via hole penetrating from the second surface of the second insulation layer to the land conductor; and a via hole conductor located in the via hole and in contact with the land conductor. The via hole conductor includes an underlying metal layer and an electrolytic plating layer located on the underlying metal layer, the underlying metal layer being located on a surface of the land conductor, a wall surface of the via hole, and the second surface. A plurality of voids are located in at least a portion of the underlying metal layer.

With regard to the embodiment of the present disclosure, the following embodiments (2) to (11) will be further disclosed.
(2) In the wiring board according to (1), wherein the underlying metal layer is an electroless plating layer.
(3) In the wiring board according to (1), the underlying metal layer is a sputtered metal layer.
(4) In the wiring board according to (3), wherein the sputtered metal layer includes a multilayer structure.
(5) In the wiring board according to any one of (1) to (4), the land conductor includes an inclined portion at a peripheral edge of the land conductor. The thickness of the inclined portion increases from the peripheral edge of the land conductor to the side surface of the via hole conductor in a cross-sectional view.
(6) In the wiring board according to any one of (1) to (5), the land conductor includes a concave portion that is recessed in a curved shape in a cross-sectional view. The via hole conductor is in contact with the concave portion.
(7) In the wiring board according to any one of (1) to (6), the via hole conductor includes a constricted portion having the smallest width in a horizontal direction along the first surface. The plurality of voids are located closer to the land conductor than the constricted portion at least in a direction perpendicular or substantially perpendicular to the first surface of the via hole conductor.
(8) In the wiring board according to any one of (1) to (7), the underlying metal layer includes a first region located between the electrolytic plating layer and the land conductor and a second region located between the electrolytic plating layer and the second insulation layer. A density of the plurality of voids included in the first region is greater than a density of the plurality of voids included in the second region.
(9) In the wiring board according to (8), the first region includes one or more and forty or less voids of the plurality of voids per 1000000 nm² in a cross-sectional view.
(10) In the wiring board according to (9), the underlying metal layer is the electroless plating layer, and the first region includes one or more and forty or less voids of the plurality of voids per 1000000 nm² in a cross-sectional view.
(11) In the wiring board according to (9), the underlying metal layer is the sputtered metal layer, and the first region includes one or more and ten or less voids of the plurality of voids per 1000000 nm² in a cross-sectional view.
(12) A mounting structure according to the present disclosure includes a wiring board according to any one of (1) to (11) described above, and an electronic component located on a mounting region of the wiring board.

### REFERENCE SIGNS

1 Wiring board
2 Insulation layer
20 Core insulation layer
20a Through-hole conductor
21 First insulation layer
211 First surface
22 Second insulation layer
222 Second surface
3 Electrical conductor layer
31 Via hole
3a Land conductor
3a1 Concave portion
3b Via hole conductor
3b1 Electroless plating layer
3b11 First region
3b12 Second region
3b2 Electrolytic plating layer
3bK Constricted portion
32 Void
4 Solder resist
5 Solder
6 Seed layer
61 First seed layer
62 Second seed layer
63 Electrolytic plating layer
631 Depression
7 Resist
8 Sputtered metal layer
81 First sputtered metal layer
82 Second sputtered metal layer

1.

1. A wiring board comprising:
a first insulation layer having a first surface;
a land conductor located on the first surface;
a second insulation layer covering the first surface and the land conductor and having a second surface on a side opposite to the first insulation layer;
a via hole penetrating from the second surface of the second insulation layer to the land conductor; and
a via hole conductor located in the via hole and in contact with the land conductor, wherein
the via hole conductor comprises an underlying metal layer and an electrolytic plating layer located on the underlying metal layer, the underlying metal layer being located on a surface of the land conductor, a wall surface of the via hole, and the second surface, and
a plurality of voids are located in at least a portion of the underlying metal layer.

2. The wiring board according to claim 1, wherein
the underlying metal layer is an electroless plating layer.

3. The wiring board according to claim 1, wherein
the underlying metal layer is a sputtered metal layer.

4. The wiring board according to claim 3, wherein
the sputtered metal layer has a multilayer structure.

5. The wiring board according to claim 1, wherein
the land conductor comprises an inclined portion at a peripheral edge of the land conductor, and
a thickness of the inclined portion increases from a peripheral edge of the land conductor to a side surface of the via hole conductor in a cross-sectional view.

6. The wiring board according claim 1, wherein
the land conductor comprises a concave portion that is recessed in a curved shape in a cross-sectional view, and
the via hole conductor is in contact with the concave portion.

7. The wiring board according claim 1, wherein
the via hole conductor comprises a constricted portion comprising a smallest width in a horizontal direction along the first surface, and
the plurality of voids are located at least closer to the land conductor than the constricted portion in a direction perpendicular to the first surface in the via hole conductor.

8. The wiring board according to claim 1, wherein
the underlying metal layer comprises a first region located between the electrolytic plating layer and the land conductor and a second region located between the electrolytic plating layer and the second insulation layer, and
a density of the plurality of voids comprised in the first region is higher than a density of the plurality of voids comprised in the second region.

9. The wiring board according to claim 8, wherein
the first region comprises one or more and forty or less voids of the plurality of voids per 1000000 nm² in a cross-sectional view.

10. The wiring board according to claim 9, wherein
the underlying metal layer is the electroless plating layer, and
the first region comprises one or more and forty or less voids of the plurality of voids per 1000000 nm² in a cross-sectional view.

11. The wiring board according to claim 9, wherein
the underlying metal layer is the sputtered metal layer, and
the first region comprises one or more and ten or less voids of the plurality of voids per 1000000 nm² in a cross-sectional view.

12. A mounting structure comprising:
the wiring board according to claim 1; and
an electronic component located at a mounting region of the wiring board.
